(19) United States
(12) Patent Application Publication
(10) Pub. No.: US 2018/0188318 A1
(43) Pub. Date: Jul. 5, 2018

(54) DUAL-FEED TEST HANDLING SYSTEM

(71) Applicant: ASM Technology Singapore Pte Ltd, Singapore (SG)

(72) Inventors: Cho Tao CHEUNG, Yeun Long (HK); Chi Wah CHENG, Tsing Yi (HK); Kai Fung LAU, North Point (HK)

(21) Appl. No.: 15/395,061

(22) Filed: Dec. 30, 2016

(51) Int. Cl. G01R 31/28

(52) U.S. Cl. CPC G01R 31/2893

(57) ABSTRACT

A test handler for testing electronic components comprises a rotary turret for conveying electronic components, a first input station and a second input station, the first and second input stations each being operative to separately feed electronic components to the rotary turret for conveying the electronic components. The electronic components fed only from the first input station are tested at a first set of test stations comprising a plurality of first test platforms, and the electronic components fed only from the second input station are tested at a second set of second test stations comprising a plurality of second test platforms. For removing the electronic components from the rotary turret, a first off-loading station receives electronic components fed only from the first input station and a second off-loading station receives electronic components fed only from the second input station.

### FIELD OF THE INVENTION

The invention relates to a test handling system for testing electronic components and in particular to a high-speed rotary turret used for conveying electronic components to respective test stations for testing.

### BACKGROUND AND PRIOR ART

FIG. 1 is a plan view of a conventional test handler 100 for testing electronic components. FIG. 2 is an isometric view of the conventional test handler 100 shown in FIG. 1. The test handler 100 generally comprises a high-speed rotary turret 102 which has multiple pick heads to pick up electronic components that are fed from an input station 104. The input station 104 may include a vibration bowl feeder or other automatic feeding means.

Electronic components are individually picked up by the pick heads on the rotary turret 102, and are subsequently conveyed to various functional test stations 108 to conduct one or more tests before they are qualified for use. The functional test stations 108 may comprise various tests, such as electrical and/or optical tests. After testing, electronic components that pass such testing conducted on them are usually off-loaded at an off-loading station 106, and then packed into carrier tapes (or other storage media such as plastic tubes or bins) for shipment.

FIG. 3 is an isometric view of a functional test station 108 of the test handler 100 and pick heads 110 for placing electronic components 112 at the functional test station 108 for testing. The pick heads 110 are arranged along a periphery of the rotary turret 102, and each pick head 110 is operative to pick up and transport a single electronic component 112 when it moves with the rotation of the rotary turret 102.

When an electronic component 112 is conveyed to a position above a functional test station 108, the electronic device 112 is placed onto a test platform 114 comprised in the functional test station 108. The electronic component 112 is tested when it is held securely on the test platform 114. The test platform 114 may move upwards to collect an electronic component 112 from the pick head 110, or the pick head 110 may move downwards to place the electronic component 112 onto the test platform 114.

After testing of an electronic component 112 has been completed, the tested electronic component 112 is picked up again by a pick head 110, and is conveyed stepwise by rotation of the rotary turret 102 to the off-loading station 106 for removal from the test handler 100.

It is apparent that a testing cycle for a test handler 100 would comprise the time taken for transferring the electronic component 112 from the input station 104 to the functional testing station 108 (or the time taken for transferring the electronic component 112 from the functional testing station 108 to the off-loading station 106) and the time taken to test it. Since the operational process steps are sequential, no matter how fast the rotary turret 102 rotates or how much the time taken to transfer the electronic components 112 to or from various locations is reduced, the time required for testing each electronic component 112 is essentially the same and cannot be reduced significantly. The time required for testing thus results in a bottleneck that limits further reduction in operational cycle time of the conventional test handler 100.

In order to achieve a significant increase in system throughput without altering the time required for testing each electronic component 112, it would be necessary to reconfigure the conventional test handler 100. In particular, it would be beneficial if the transfer mechanisms for loading and off-loading the electronic components 112 on the rotary turret 102 in a conventional test handler 100 can be reconfigured in such a way that throughput is significantly increased without altering the time required for testing each electronic component 112.

### SUMMARY OF THE INVENTION

It is thus an object of the invention to seek to provide a reconfigured test handler that is capable of increasing the system throughput even where the time required for testing each electronic component is relatively fixed.

Accordingly, the invention provides a test handler for testing electronic components, the test handler comprising: a rotary turret for conveying electronic components; a first input station and a second input station, the first and second input stations each being operative to separately feed electronic components to the rotary turret for conveying the electronic components; a first set of test stations comprising a plurality of first test platforms for testing electronic components fed only from the first input station and a second set of second test stations comprising a plurality of second test platforms for testing electronic components fed only from the second input station; and a first off-loading station operative to receive electronic components fed only from the first input station and a second off-loading station operative to receive electronic components fed only from the second input station for removing the electronic components from the rotary turret.

It would be convenient hereinafter to describe the invention in greater detail by reference to the accompanying drawings which illustrate a specific preferred embodiment of the invention. The particularity of the drawings and the related description is not to be understood as superseding the generality of the broad identification of the invention as defined by the claims.

### BRIEF DESCRIPTION OF THE DRAWINGS

An example of a test handler system in accordance with the invention will now be described with reference to the accompanying drawings, in which:

FIG. 1 is a plan view of a conventional test handler;

FIG. 2 is an isometric view of the conventional test handler shown in FIG. 1;

FIG. 3 is an isometric view of a functional test station of the test handler and pick heads for placing electronic components at the functional test station for testing;

FIG. 4 is a plan view of a test handler according to the preferred embodiment of the invention; and

FIG. 5 is an isometric view of the test handler shown in FIG. 4.

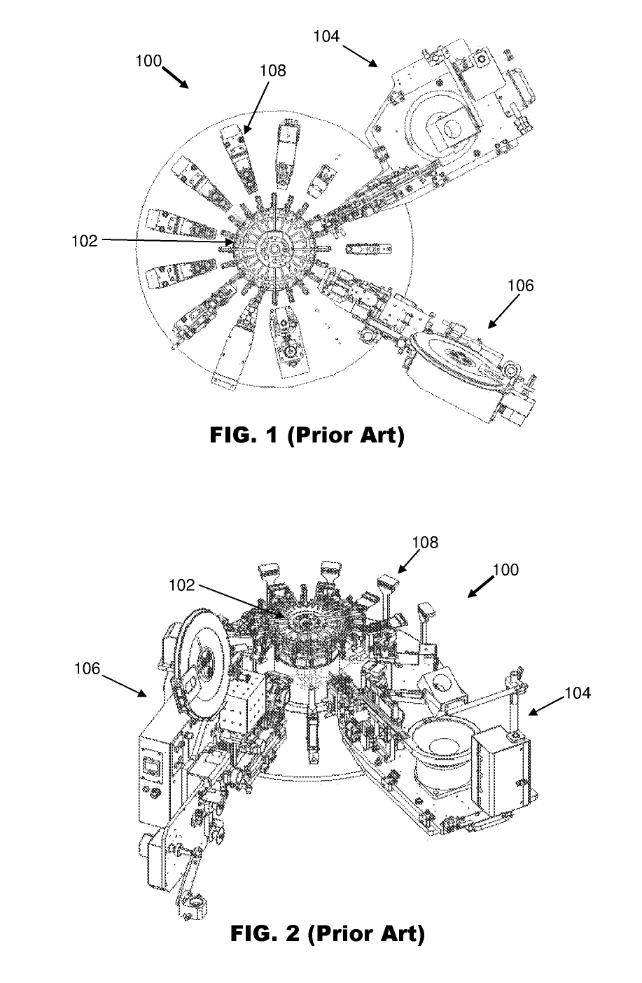

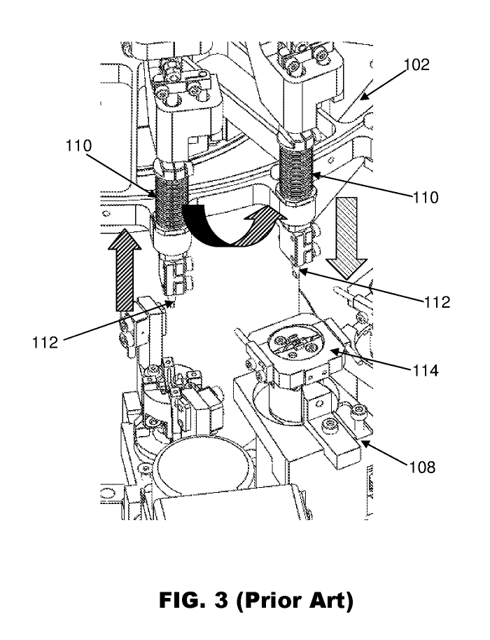

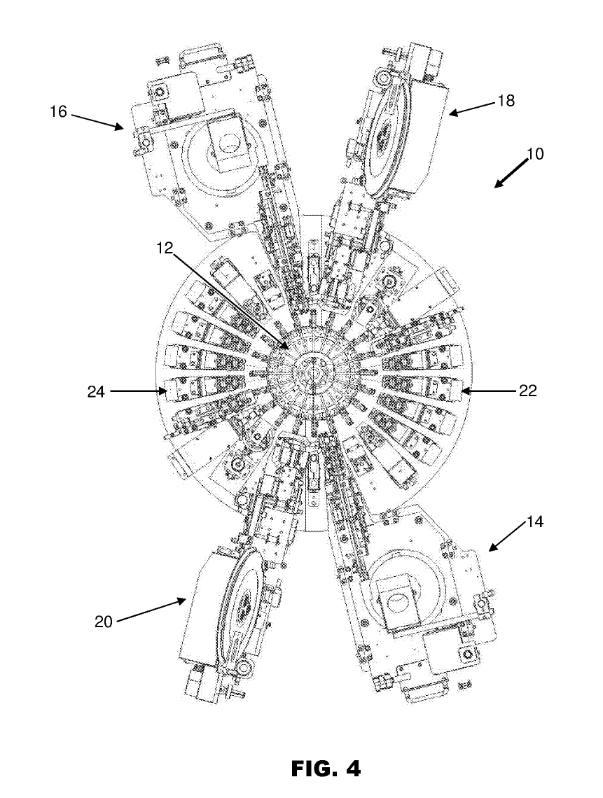

### DETAILED DESCRIPTION OF THE PREFERRED EMBODIMENT OF THE INVENTION

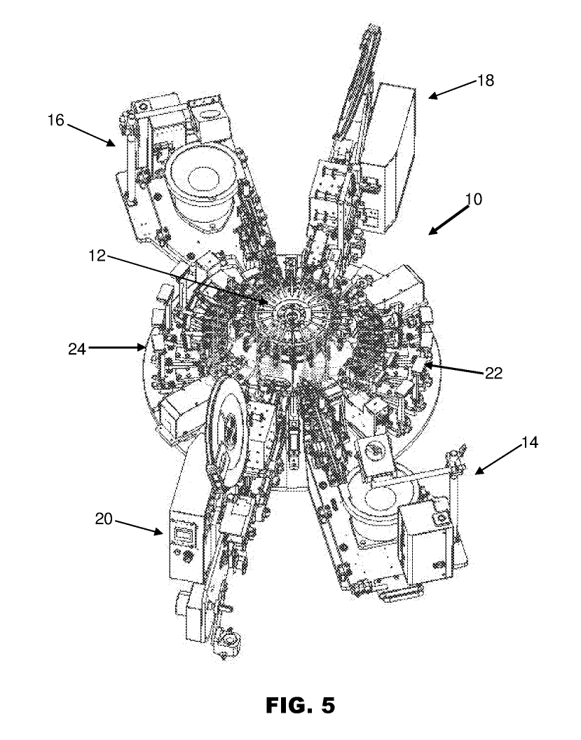

FIG. 4 is a plan view of a test handler 10 according to the preferred embodiment of the invention. FIG. 5 is an isometric view of the test handler 10 shown in FIG. 4.

The test handler 10 comprises a high-speed rotary turret 12 which has multiple pick heads to pick up electronic components 112. The test handler 10 further comprises a first input station 14 and a second input station 16, as well as a first off-loading station 18 and a second off-loading station 20. The first input station 14 on the one hand, and the first off-loading station 18 and the second input station 16 on the other, are located substantially on opposite sides of the rotary turret 12. Similarly, the second input station 16 and the second off-loading station 20 are located substantially on opposite sides of the rotary turret 12.

Moreover, the functional test stations of the test handler 10 are divided into a first set of functional test stations 22 on one side of the test handler 10, and a second set of functional test stations 24 on an opposite side of the test handler 10. The pick heads 110 located on the rotary turret 12 generally receive and hold electronic components 112 fed from both the first and second input stations 14, 16, and convey tested electronic components to both the first and second off-loading stations 18, 20.

In use, electronic components 112 are simultaneously fed to the pick heads 110 of the rotary turret 12 from the first input station 14 and the second input station 16 separately. Electronic components 112 which are fed only from the first input station 14 are conveyed by the rotary turret 12 to be tested at test platforms 114 from the first set of functional test stations 22. After testing at the first set of functional test stations 22, the electronic components 112 are conveyed to the first off-loading station 18 for removal from the test handler 10.

On the other hand, electronic components 112 which are fed only from the second input station 16 are conveyed by the rotary turret 12 to be tested at test platforms 114 from the second set of functional test stations 24. After testing at the second set of functional test stations 24, the electronic components 112 are conveyed to the second off-loading station 20 for removal from the test handler 10.

Hence, the test handler 10 is essentially divided into two halves, wherein one-half of the rotary turret 12 is served by the first input station 14, the first off-loading station 18 and the first set of functional test stations 22, and another one-half of the rotary turret 12 is served by the second input station 16, the second off-loading station 20 and the second set of functional test stations 24.

In the aforesaid arrangement, the first input station 14, the first off-loading station 18 and the first set of functional test stations 22 are located substantially along a first half of the rotary turret 12. The second input station 16, the second off-loading station 20 and the second set of functional test stations 24 are located substantially along a second half of the rotary turret 12 that does not overlap with the first half of the rotary turret 12. This arrangement allows the two sets of electronic components 112 to be fed and tested at the first and second sets of functional test stations 22, 24 in parallel, although the same rotary turret 12 is used.

By adopting the test handler arrangement in accordance with the preferred embodiment of the invention, it is possible to obtain up to double the throughput as compared with conventional test handler arrangements whilst the testing time for electronic components remains unchanged. Such benefit is possible without employing two separate test handlers, and is thus much more cost-effective since it requires only one rotary turret system.

The invention described herein is susceptible to variations, modifications and/or additions other than those specifically described and it is to be understood that the invention includes all such variations, modifications and/or additions which fall within the spirit and scope of the above description.

1. A test handler for testing electronic components, the test handler comprising:
a rotary turret for conveying electronic components;
a first input station and a second input station, the first and second input stations each being operative to separately feed electronic components to the rotary turret for conveying the electronic components;
a first set of test stations comprising a plurality of first test platforms for testing electronic components fed only from the first input station and a second set of second test stations comprising a plurality of second test platforms for testing electronic components fed only from the second input station; and
a first off-loading station operative to receive electronic components fed only from the first input station and a second off-loading station operative to receive electronic components fed only from the second input station for removing the electronic components from the rotary turret.

2. The test handler as claimed in claim 1, further comprising multiple pick heads located on the rotary turret which are operative to receive and convey the electronic components from both the first and second input stations, and to convey tested electronic components to both the first and second off-loading stations.

3. The test handler as claimed in claim 1, wherein the first and second input stations are located substantially on opposite sides of the rotary turret.

4. The test handler as claimed in claim 3, wherein the first and second off-loading stations are located substantially on opposite sides of the rotary turret.

5. The test handler as claimed in claim 3, wherein the first input station and the first off-loading station are located substantially on opposite sides of the rotary turret.

6. The test handler as claimed in claim 3, wherein the second input station and the second off-loading station are located substantially on opposite sides of the rotary turret.

7. The test handler as claimed in claim 3, wherein the first test platforms are located substantially along a first half of the rotary turret, and the second test platforms are located substantially along a second half of the rotary turret that does not overlap with the first half of the rotary turret.

8. The test handler as claimed in claim 1, wherein one-half of the rotary turret is served by the first input station, first test platforms and first off-loading station, and another one-half of the rotary turret is served by the second input station, second test platforms second first off-loading station.

9. The test handler as claimed in claim 1, wherein the electronic components fed from the first input station are tested at the first set of test stations in parallel with the electronic components fed from the second input station being tested at the second set of test stations.
